(19) United States
(12) Patent Application Publication
(10) Pub. No.: US 2009/0303779 A1
(43) Pub. Date: Dec. 10, 2009

(54) Spin Torque Transfer MTJ Devices with High Thermal Stability and Low Write Currents

(76) Inventors: Young-Shying Chen, Danshuei (TW); Yung-Hung Wang, Dasi (TW); Yu-Jen Wang, Hsin-Chu (TW); Chun-Jung Lin, Hsin-Chu (TW)

Correspondence Address: SLATER & MATSIL, L.L.P., 17950 PRESTON ROAD, SUITE 1000, DALLAS, TX, 75252, US

(21) Appl. No.: 12/133,865

(22) Filed: Jun. 5, 2008

(51) Int. Cl. G11C 11/02

(52) U.S. Cl. 365/158

(57) ABSTRACT

An integrated circuit structure includes a first fixed magnetic element; a second fixed magnetic element; and a composite free magnetic element between the first and the second fixed magnetic elements. The composite free magnetic element includes a first free layer and a second free layer.

### TECHNICAL FIELD

The present invention relates generally to semiconductor memory devices, and more particularly to spin torque transfer (STT) magnetic tunnel junction (MTJ) devices and methods of manufacturing the same.

### BACKGROUND

Semiconductors are used in integrated circuits for electronic applications, including radios, televisions, cell phones, and personal computing devices. One type of semiconductor device is a semiconductor storage device, such as dynamic random access memories (DRAM), or flash memories, both of which use charges to store information.

A more recent development in semiconductor memory devices involves spin electronics, which combines semiconductor technology and magnetic materials and devices. The spin polarization of electrons, rather than the charge of the electrons, is used to indicate the state of a “1” or “0.” One such spin electronic device is a spin torque transfer (STT) magnetic tunneling junction (MTJ) device 10, sometimes referred to as magneto-resistive random access memory (MRAM) device 10, as shown in FIG. 1.

MRAM device 10 includes free layer 12, tunnel layer 14, and pinned layer 16. The magnetization direction of free layer 12 is reversible by applying a current through tunnel layer 14, which causes the injected polarized electrons within free layer 12 to exert so-called spin torques on the magnetization of free layer 12. Pinned layer 16 has a fixed magnetization direction. When current I1 flows in the direction from free layer 12 to pinned layer 16, electrons flow in a reverse direction, that is, from pinned layer 16 to free layer 12. The electrons are polarized to the same magnetization direction of pinned layer 16 after passing pinned layer 16; flowing through tunnel layer 14; and then into and accumulating in free layer 12. Eventually, the magnetization of free layer 12 is parallel to that of pinned layer 16, and MRAM device 10 will be at a low resistance state. The electron injection caused by current I1 is referred to as a major injection.

When a current I2, flowing from pinned layer 16 to free layer 12, is applied, electrons flow in the direction from free layer 12 to pinned layer 16. An electron, which with polarization is the same direction as magnetization of pinned layer 16, is able to flow through tunnel layer 14, and into pinned layer 16. An electron with polarization differing from the magnetization of pinned layer 16 will be reflected (blocked) by pinned layer 16, and accumulate in free layer 12. Eventually, magnetization of free layer 12 becomes anti-parallel to that of pinned layer 16, and MRAM device 10 will be at a high-resistance state. The respective electron injection caused by current I2 is referred to as a minor injection.

The write current required for reversal a state of a MRAM device as shown in FIG. 1 may be roughly expressed as being proportional to the square of free layer magnetization Ms. Unfortunately, the energy barrier of the MRAM devices may also be roughly expressed as proportional to the square of free layer magnetization Ms. Typically, it is desirable to reduce the write currents of MRAM devices. However, the decrease in the write currents also results in the reduction in the energy barrier, which is closely related to the thermal stability of MRAM cells. Experiment results have revealed that if the duration of the write pulses increases, the write current may be reduced without affecting the write ability. This adversely causes the instability of the MRAM devices. For example, the read disturbance may cause the data stored in MRAM cells to be lost. The data retention time of MRAM cells is also adversely affected by the reduced thermal stability.

FIG. 2 illustrates conventional MRAM cell 20, which includes free layers 22 and 26, spacer layer 24, tunnel layer 28, and pinned layer 29. Spacer layer 24 couples the magnetizations between free layers 22 and 26, so that when the magnetization direction of the free layer 26 is reversed, the magnetization direction of the other free layer 22 is also reversed. This structure has an increased energy barrier, which may be close to twice the energy barrier of the MRAM cell 10 shown in FIG. 1. Accordingly, the thermal stability of MRAM cell 20 is better than that of MRAM cell 10.

The MRAM cell 20, however, suffers from drawbacks of increased writing current (or at least not optimized). When the coupling between layers 22 and 26 is not optimized, it needs higher writing current to generate spin toque in order to overcome the retard of coupling. New MRAM cells are thus needed to solve the above-discussed problems.

### SUMMARY OF THE INVENTION

In accordance with one aspect of the present invention, an integrated circuit structure includes a first fixed magnetic element; a second fixed magnetic element; and a composite free magnetic element between the first and the second fixed magnetic elements. The composite free magnetic element includes a first free layer and a second free layer.

In accordance with another aspect of the present invention, an integrated circuit structure includes a first fixed magnetic element; a second fixed magnetic element, wherein the first and the second fixed magnetic elements have parallel magnetization directions; a composite free magnetic element between the first and the second fixed magnetic elements, wherein the composite free magnetic element includes a first free layer and a second free layer having anti-parallel magnetization directions; a conductive spacer adjoining the first fixed magnetic element and the composite free magnetic element; and a tunnel layer adjoining the second fixed magnetic element and the composite free magnetic element.

In accordance with yet another aspect of the present invention, an integrated circuit structure includes a memory array, which includes a magneto-resistive random access memory (MRAM) cell. The MRAM cell includes a first fixed magnetic element; a second fixed magnetic element; a composite free magnetic element between the first and the second fixed magnetic elements, wherein the composite free magnetic element comprises a first free layer and a second free layer; a conductive spacer adjoining the first fixed magnetic elements and the composite free magnetic element; and a tunnel layer adjoining the second fixed magnetic elements and the composite free magnetic element. The memory array further includes a bit line electrically connected to a first end of the MRAM cell, a drain of select transistor electrically connected to a second end of the MRAM cell, a word line electrically connected to gate of a select transistor, and a source line electrically connected to a source of select transistor.

The advantageous features of the present invention include increased energy barriers and/or reduced write currents of MRAM cells. The possible stray magnetic fields are substantially reduced, and possibly eliminated.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional magneto-resistive random access memory (MRAM) device having one free layer;

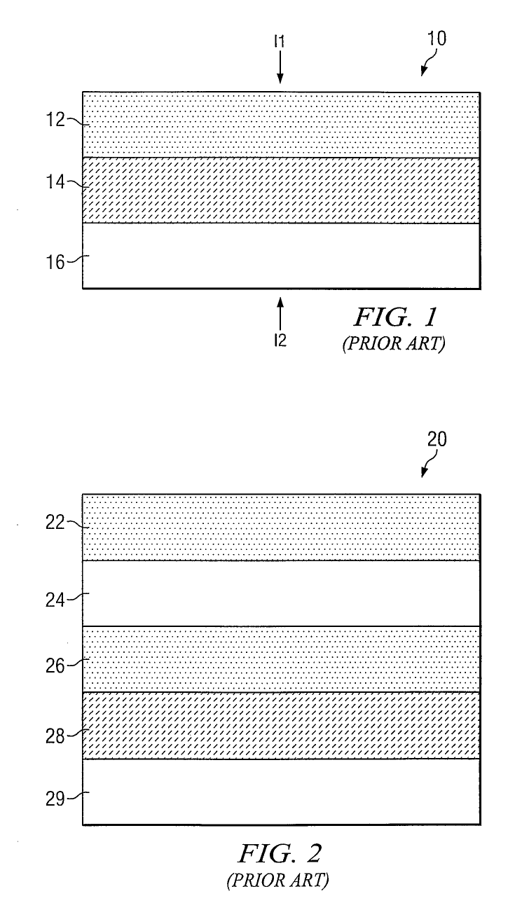

FIG. 2 illustrates a conventional MRAM device having two free layers (alternatively referred to as a composite free layer);

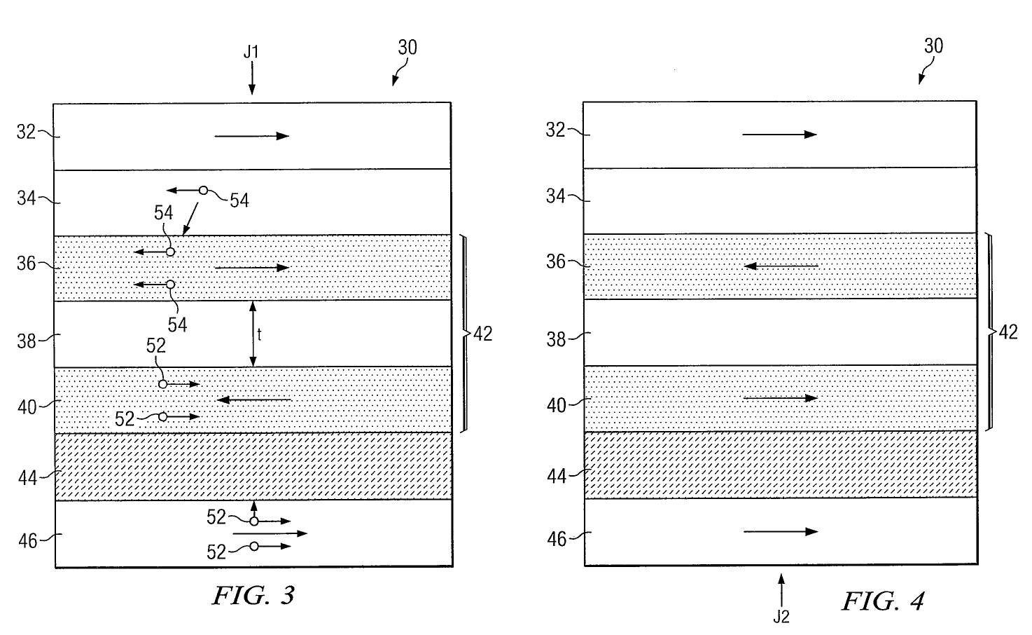

FIGS. 3-7 are MRAM embodiments of the present invention, wherein each MRAM device includes at least two pinned layers and two free layers; and

FIG. 8 illustrates a memory array formed of the MRAM embodiments of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel magneto-resistive random access memory (MRAM) device (also referred to as spin torque transfer (STT) magnetic tunnel junction (MTJ) device) and the method of forming the same are presented. The variations and operations of the preferred embodiments are discussed. Throughout the various views and illustrative embodiments of the present invention, like reference numbers are used to designate like elements.

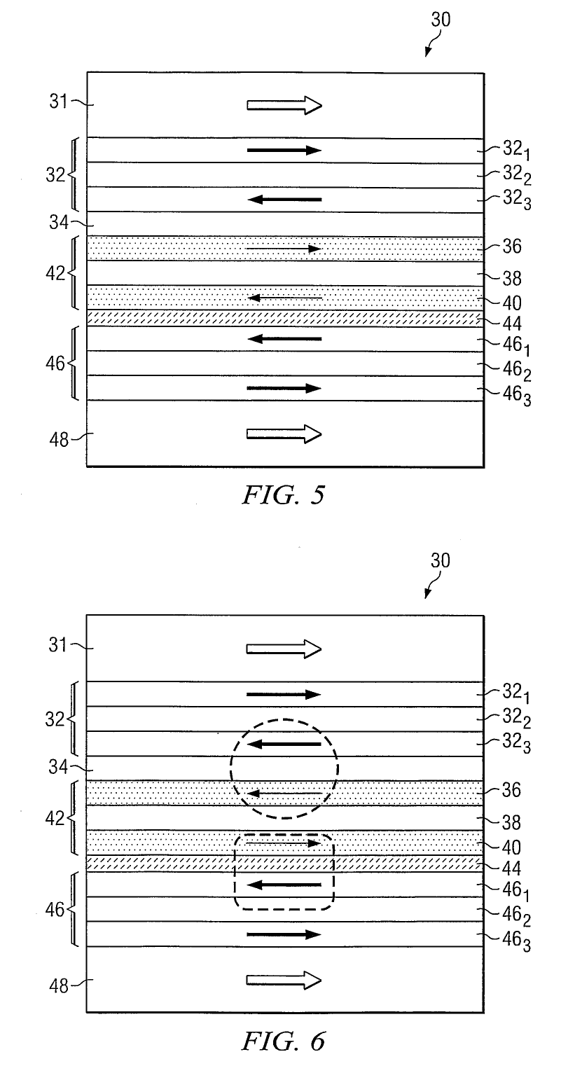

FIG. 3 illustrates an embodiment of the present invention. MRAM device 30 includes pinned layer 32, spacer 34, free layer 36, coupling layer 38, free layer 40, tunnel layer 44, and pinned layer 46. The state of MRAM cell 30 is determined by the magnetization directions of free layer 40 and pinned layer 46. If the magnetization directions of free layer 40 and pinned layer 46 are parallel, the state of MRAM cell 30 is a low-resistance state. Conversely, if the magnetization directions of free layer 40 and pinned layer 46 are anti-parallel, the state of MRAM cell 30 is a high-resistance state. Throughout the description, “anti-parallel” is construed as a different concept than “parallel.”

Free layer 36, coupling layer 38, and free layer 40 in combination are referred to as synthetic anti-parallel ferromagnetic (SAF) free layer 42 throughout the description. In an embodiment, free layers 36 and 40 are formed of magnetic materials such as Ni, Fe, Mn, Co, and their alloys such as CoFeB, CoFe, NiFe, and the like. Half-metallic ferro-magnetic materials, such as NiMnSb, PtMnSb, PtMnSb, Fe₃O₄, CrO₂, CoCr, CoPt, CoCrPt, CoFe, CoFeCr, CoFePt, CoFeCrPt, and the like, may also be used. Their magnetization directions of free layers 36 and 40, as their name suggests, are current programmable. Coupling layer 38 may be formed of Ru, Cu, and the like. The thickness t of coupling layer 38 affects the coupling (known as RKKY coupling) between free layers 36 and 40, and hence needs to be adjusted to control the coupling between free layers 36 and 40 to a desirable state. In the preferred embodiment of the present invention, magnetizations of free layers 36 and 40 are anti-parallel (in opposite directions in the plane of free layers 36 and 40), as is shown in FIG. 3. In other embodiments, free layers 36 and 40 may be parallel (in a same direction in the plane of free layers 36 and 40). The thickness t and possibly the material of coupling layer 38 control whether the coupling between free layers 36 and 40 is parallel or anti-parallel. When thickness t is changed, the coupling of free layers 36 and 40 may change from the anti-parallel state to the parallel state, or from the parallel state to the anti-parallel state. With the increase in the thickness t of coupling layer 38, however, the coupling effect decreases. In the exemplary embodiment wherein free layers 36 and 40 are anti-parallel, a coupling layer 38 formed of Ru may have thickness 0.8 or 2 nm corresponding to the first and second anti-parallel RKKY peak location.

Spacer layer 34 is preferably formed of a conductive and non-magnetic material. Exemplary materials include Ru, Os, Re, Cr, Rh, Cu, and combinations thereof. In alternative embodiments, it is preferable that spacer layer 34 is formed of materials similar to that of tunnel layer 44, such as a significantly small RA (a product of resistance and area) value of MgO.

Tunnel layer 44 is preferably formed of a metal oxide or a metal nitride, or combinations thereof. Exemplary materials include metal oxides and/or metal nitrides of Al, Mg, Hf, Sr, Ti, and combinations thereof. An exemplary thickness of tunnel layer 44 is between about 0.3 and 2 nm.

Pinned layers 32 and 46 (also referred to as fixed magnetic elements throughout the description) have fixed magnetization directions, and may include magnetic materials such as Ni, Fe, Mn, Co, or alloys thereof, such as CoFeB, CoFe, NiFe, and the like. Also, half-metallic ferro-magnetic materials such as NiMnSb, PtMnSb, Fe₃O₄, CrO₂, and the like, may be used. In the preferred embodiment, pinned layers 32 and 46 have parallel magnetization directions, as is shown in FIG. 3, although the magnetization directions may also be anti-parallel.

Exemplary operations of MRAM cell 30 are discussed as follows, wherein it is assumed that pinned layers 32 and 46 have parallel magnetization directions, and magnetizations of free layers 36 and 40 are anti-parallel coupled. It is appreciated that the real mechanism may be more complicated. Assuming MRAM cell 30 was initially at a high-resistance state, that is, the magnetization directions of free layer 40 and pinned layer 46 are anti-parallel, when a write current J1 is applied, electrons flow in an opposite direction of current J1. The polarized electrons (symbolized as electrons 52, wherein the arrows connected to the electrons symbolize magnetization directions) with a same magnetization direction as pinned layer 46 flow through tunnel layer 44 and into free layer 40. These electrons 52 exert a spin torque on the magnetization of free layer 40. Since the spin toque is originated by the polarized electrons from pinned layer 46, the above-discussed injection is referred to as a major injection.

Because of the major-injection electrons 52 in free layer 40 and the anti-parallel coupling between free layers 40 and 36, the electrons of free layer 40 with polarizations anti-parallel to the magnetization direction of pinned layer 46 favor to flow into free layer 36. The electrons 54 with polarizations anti-parallel to the magnetization direction of pinned layer 32 are blocked (reflected) by pinned layer 32, and accumulating in free layer 36. These electrons 54 also exert a spin torque exert on the magnetization of free layer 36. Since the spin toque is originated by the electrons with polarization anti-parallel to the magnetization direction of pinned layer 32, it could be referred to as a minor injection.

Both of the free layers 36 and 40 simultaneously impose spin toques of minor injection and major injection, hence the retard of coupling is released, causing the magnetizations of free layers 36 and 40 coherently reversed to the direction for spin toques transfer. Accordingly, the magnetization directions of free layers 36 and 40 are altered to anti-parallel and parallel to that of pinned 46, respectively. After the magnetization directions of free layers 36 and 40 are reversed, the electrons 52 and 54 no longer exert spin toque, and hence the magnetizations of free layer 36 and 40 may remain stable. The state of MRAM cell 30 is thus changed from the high-resistance state to the low-resistance state. The write current can thus be reduced. Advantageously, since MRAM cells have coupling dual-free-layer structure, the energy barrier is increased to twice of the conventional MRAM cells having single-free-layer structures. This also means the write current can be reduced to only a half of the conventional MRAM cells while still keeping the same energy barrier as the conventional MRAM cells. In other words, if MRAM cell embodiments having a same write current as the conventional single-free-layer MRAM cells are to be designed, the energy barrier of the MRAM cell embodiments of the present invention will be twice that of the conventional single-free-layer MRAM cells.

If the state of the MRAM cell 30 is to be changed from the low-resistance state to the high-resistance state, a current J2, as shown in FIG. 4, be applied. Electrons thus flow in the direction from pinned layer 32 into free layer 36. Similarly, the major injection, which involves electrons flowing into free layer 36, will exert a spin toque on the magnetization of free layer 36 reverse its direction parallel to that of pinned layer 32. The minor injection, which involves electrons reflected back to free layer 40 by pinned layer 46, will also exert a spin toque on the magnetization of free layer 40 and reverse its direction anti-parallel to that of pinned layer 46. The reversal of the magnetization directions of free layers 36 and 40 are coherent and the same mechanism as description in preceding paragraph.

In the embodiment shown in FIG. 3, each of the pinned layers 32 and 46 may be a composite layer. FIG. 5 illustrates an embodiment in which both pinned layers 32 and 46 are composite layers. The composite pinned layer 32 includes pinned sub layers 32₁ and 32₃, and coupling sub layer 32₂ to coupling the magnetization between pinned sub layers 32₁ and 32₃. The magnetization direction of pinned sub layer 32₃, which is close to spacer 34, is referred to as the magnetization direction of the composite pinned layer 32 hereinafter. Similarly, composite pinned layer 46 includes pinned sub layers 46₁ and 46₃, and coupling sub layer 46₂ to coupling the magnetization between pinned sub layers 46₁ and 46₃. The magnetization direction of pinned sub layer 46₁, which is close to tunnel layer 44, is referred to as the magnetization direction of the composite pinned layer 46. The state of MRAM cell 30 shown in FIG. 5 depends on whether the magnetization directions of pinned sub layers 46₁ and free layer 40 are parallel or anti-parallel.

In the preferred embodiment, the magnetization directions of pinned sub layers 32₃ and 46₁ are parallel (which means composite pinned layers 32 and 46 have parallel magnetization directions), and the magnetization directions of free layers 36 and 40 are anti-parallel. By coherently reversing the anti-parallel magnetization directions of free layers 36 and 40, the state of MRAM cell 30 as shown in FIG. 5 may be changed. The operations are similar to those shown in FIGS. 3 and 4, and thus are not repeated herein. FIG. 5 illustrates the MRAM cell being in the low-resistance state, while FIG. 6 illustrates a MRAM cell in the high-resistance state.

FIG. 5 also illustrates top pinning layer 31 and bottom pinning layer 48, which have fixed magnetization directions, and are used to fix the pinned layers 46₃ and 32₁ to the desirable magnetization directions. Pinning layers 31 and 48 may be formed of anti-ferromagnetic materials such as PtMn, IrMn, and the like. Coupling layer 32₂ has the function of fixing the magnetization direction of pinned sub layers 32₃ by coupling the magnetization directions of pinned layers 32₁ and 32₃. Similarly, coupling 46₂ has the function of fixing the magnetization direction of pinned sub layers 46₁ by coupling the magnetization directions of pinned layers 46₁ and 46₃. In the preferred embodiment, the thickness of coupling layers 32₂ and 46₂ are selected so that pinned sub layers 32₁ and 32₃ are anti-parallel, and pinned sub layers 46₁ and 46₃ are anti-parallel, although they can also be parallel.

Advantageously, each of the composite pinned layers 32 and 46 include two pinned sub layers having anti-parallel magnetic directions. Therefore, the pinned sub layers in each of the composite pinned layers 32 and 46 form a closed loop, so that the strayed magnetic field is balanced, and hence the effect of the strayed magnetic field to free layers 36 and 40 are at least reduced, and possibly substantially eliminated. The close loop also makes adjusting the RH loop of the MRAM cell 30 easy.

FIG. 7 illustrates yet another embodiment of the present invention, wherein one of the pinned layers, for example pinned layer 32, is a single layer; while the other pinned layer, such as pinned layer 46, is a composite layer. In the illustrated example, pinned layer 46 has three pinned sub layers 46₁, 46₃, and 46₅, which are coupled by coupling layers 46₂ and 46₄. Again, the magnetization direction of pinned sub layer 46₅ is fixed by pinning layer 48, while the magnetization directions of pinned sub layers 46₁ and 46₃ are fixed and determined by the (thicknesses) of coupling layers 46₂ and 46₄. Preferably, the magnetization directions of pinned layer 32 and pinned sub layer 46₁ are parallel, and the magnetization directions of free layers 36 and 40 are anti-parallel. The magnetization direction of pinned layer 46₃ can be either parallel or anti-parallel to that of pinned layer 46₁. One skilled in the art will realize there are many variations as to the design of pinned layers 32 and 46.

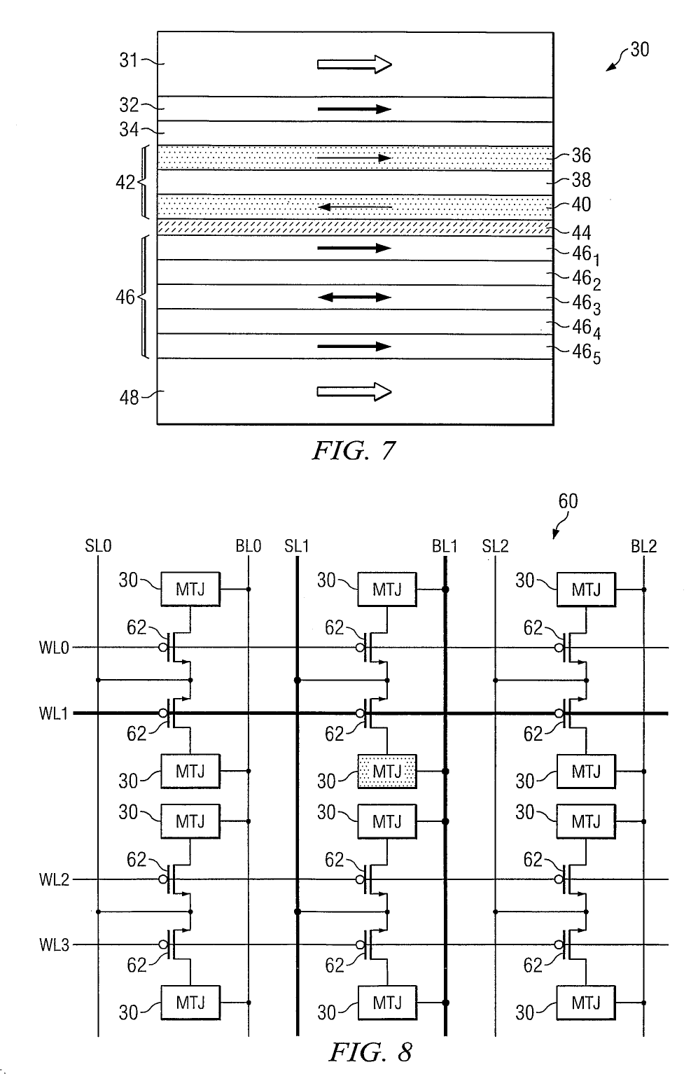

FIG. 8 illustrates MRAM array 60 formed of the MRAM cell embodiments of the present invention. MRAM cells 30 are arranged as array 60 having columns and rows. Each of the MRAM cells 30 is connected between one of the bit lines BL (referred to as BL0, BL1, . . . and the like.) and one of the source lines SL (referred to as SL0, SL1, . . . and the like). Select transistor 62 is controlled by one of word lines WL (referred to as WL0, WL1, . . . and the like). The write currents of MRAM cells 30 are applied between the bit lines BL and the source lines SL. Word lines WL also control which one of the MRAM cells 30 is operated.

The embodiments of the present invention have several advantageous features. First, with the coupling dual-free-layer scheme, the energy barrier is substantially doubled. The coherent switching utilizes both major and minor injections, and hence writing currents may be reduced. With the symmetric structures inside the composite pinned layers, the stray magnetic fields may be substantially eliminated, and the RH loops of the resulting MRAM cells are easy to adjust.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure comprising:
a first fixed magnetic element;
a second fixed magnetic element; and
a composite free magnetic element between the first and the second fixed magnetic elements, wherein the composite free magnetic element comprises a first free layer and a second free layer.

2. The integrated circuit structure of claim 1, wherein the first and the second fixed magnetic elements have parallel magnetization directions.

3. The integrated circuit structure of claim 1, wherein the first and the second free layers have anti-parallel magnetization directions.

4. The integrated circuit structure of claim 1, wherein the first fixed magnetic element comprises a first pinned sub layer, a second pinned sub layer, and a first coupling layer adjoining, and coupling magnetizations of, the first and the second pinned sub layers.

5. The integrated circuit structure of claim 4, wherein the second fixed magnetic element comprises a third pinned sub layer, a fourth pinned sub layer, and a second coupling layer adjoining, and coupling magnetizations of, the third and the fourth pinned sub layers.

6. The integrated circuit structure of claim 4, wherein the first fixed magnetic element further comprises a third pinned sub layer, and a second coupling layer adjoining, and coupling magnetizations of, the second and the third pinned sub layers.

7. The integrated circuit structure of claim 1 further comprising:
a conductive spacer between the first fixed magnetic element and the composite free magnetic element; and
a tunnel layer between the second fixed magnetic element and the composite free magnetic element.

8. The integrated circuit structure of claim 1 further comprising a coupling layer between the first and the second free layers, wherein the coupling layer is formed of a non-magnetic material.

9. An integrated circuit structure comprising:
a first fixed magnetic element;
a second fixed magnetic element, wherein the first and the second fixed magnetic elements have parallel magnetization directions;
a composite free magnetic element between the first and the second fixed magnetic elements, wherein the composite free magnetic element comprises a first free layer and a second free layer having anti-parallel magnetization directions;
a conductive spacer adjoining the first fixed magnetic element and the composite free magnetic element; and
a tunnel layer adjoining the second fixed magnetic element and the composite free magnetic element.

10. The integrated circuit structure of claim 9, wherein the composite free magnetic element further comprises a coupling layer between the first and the second free layers, wherein the coupling layer is formed of a non-magnetic material.

11. The integrated circuit structure of claim 10, wherein the coupling layer comprises a material selected from the group consisting essentially of Ru, Cu, and combinations thereof.

12. The integrated circuit structure of claim 9, wherein the conductive spacer comprises a non-magnetic material selected from the group consisting essentially of Ru, Cu, and combinations thereof.

13. The integrated circuit structure of claim 9, wherein the conductive spacer may be a low RA value of metal oxide or metal nitride.

14. The integrated circuit structure of claim 9, wherein the first fixed magnetic element comprises a first pinned sub layer and a second pinned sub layer, and a first coupling layer adjoining, and coupling magnetizations of, the first and the second pinned sub layers.

15. The integrated circuit structure of claim 14, wherein the second fixed magnetic element comprises a third pinned sub layer and a fourth pinned sub layer, and a second coupling layer adjoining, and coupling magnetizations of, the third and the fourth pinned sub layers.

16. The integrated circuit structure of claim 14, wherein the first fixed magnetic element further comprises a third pinned sub layer, and a second coupling layer adjoining, and coupling magnetizations of, the second and the third pinned sub layers.

17. The integrated circuit structure of claim 9 further comprising a first pinning layer adjoining the first fixed magnetic element, and a second pinning layer adjoining the second fixed magnetic element, wherein the first and the second pinning layers are formed of anti-ferro-magnetic materials.

18. An integrated circuit structure comprising:
a memory array comprising:
a magneto-resistive random access memory (MRAM) cell comprising:
a first fixed magnetic element;
a second fixed magnetic element;
a composite free magnetic element between the first and the second fixed magnetic elements, wherein the composite free magnetic element comprises a first free layer and a second free layer;
a conductive spacer adjoining the first fixed magnetic element and the composite free magnetic element; and
a tunnel layer adjoining the second fixed magnetic element and the composite free magnetic element;
a bit line electrically connected to a first end of the MRAM cell; and
a select transistor electrically connected to a second end of the MRAM cell.

19. The integrated circuit structure of claim 18 further comprising an additional select transistor having a gate connected to a word line, a source connected to a source line, and a drain connected to the second end of the MRAM cell.

20. The integrated circuit structure of claim 18, wherein the first and the second fixed magnetic elements have parallel magnetization directions, and wherein the first and the second free layers have anti-parallel magnetization directions.
